(19) United States
(12) Patent Application Publication
(10) Pub. No.: US 2012/0235631 A1
(43) Pub. Date: Sep. 20, 2012

(54) Storage Unit, Power Generation System, and Charge/Discharge System

(75) Inventors: Takeshi Nakashima, Osaka (JP); Ken Yamada, Osaka (JP); Hayato Ikebe, Osaka (JP); Ryuzo Hagihara, Osaka (JP)

(73) Assignee: SANYO ELECTRIC CO., LTD., Osaka (JP)

(21) Appl. No.: 13/486,176

(22) Filed: Jun. 1, 2012

Related U.S. Application Data
(63) Continuation of application No. PCT/JP2010/071563, filed on Dec. 2, 2010.

(30) Foreign Application Priority Data
Dec. 4, 2009 (JP) 2009-276103
Dec. 4, 2009 (JP) 2009-276351
Dec. 14, 2009 (JP) 2009-282588

(51) Int. Cl. H02J 7/00; H05K 7/20; H05K 7/00

(52) U.S. Cl. 320/107; 361/679.01; 361/690; 361/692

(57) ABSTRACT

This storage unit includes a storage portion that stores power, a converter that converts power, a first temperature detection portion arranged in the vicinity of the converter, and a housing that houses at least the converter, the first temperature detection portion, and the storage portion.

### CROSS-REFERENCE TO RELATED APPLICATIONS

The priority application numbers JP2009-276103, Storage Unit and Power Generation System, Dec. 4, 2009, Takeshi Nakashima et al., JP2009-276351, Power Generation System, Dec. 4, 2009, Takeshi Nakashima et al., and JP2009-282588, Storage Unit and Power Generation System, Dec. 14, 2009, Takeshi Nakashima et al., upon which this patent application is based are hereby incorporated by reference. This application is a continuation of PCT/JP2010/071563, Storage Unit, Power Generation System, and Charge/Discharge System, Dec. 2, 2010, Takeshi Nakashima, Ken Yamada, Hayato Ikebe, and Ryuzo Hagihara.

### BACKGROUND OF THE INVENTION

1. Field of the Invention

The present invention relates to a storage unit, a power generation system, and a charge/discharge system, and more particularly, it relates to a storage unit, a power generation system, and a charge/discharge system each including a storage portion capable of storing power.

2. Description of the Background Art

A power generation system including a storage battery capable of storing power is known in general, as disclosed in Japanese Patent Laying-Open No. 11-127546 (1999), for example.

In this power generation system, a photovoltaic power generation module is interconnected to a power grid. The photovoltaic power generation module is connected with the storage battery capable of storing power generated by the photovoltaic power generation module. The storage battery is so configured as to be capable of being charged also from the power grid. The storage battery can be discharged in a prescribed case to supply power to a prescribed load.

Although the aforementioned Japanese Patent Laying-Open No. 11-127546 does not disclose how the storage battery is placed when the system is actually placed, the storage battery is conceivably used by housing the storage battery and a device necessary for charge/discharge of the storage battery in a housing in order to protect the storage battery in a case of placing the storage battery outdoors, for example. However, the temperature (temperature of the storage battery) in the housing is disadvantageously easily increased by heat generated from the aforementioned device and direct sunlight in the case of housing the storage battery in the housing. If the temperature in the housing is increased, the storage battery may be negatively influenced by the increased temperature.

### SUMMARY OF THE INVENTION

An object of the present invention is to provide a storage unit, a power generation system, and a charge/discharge system each capable of inhibiting a storage battery from being negatively influenced even in a case of using the storage battery by housing the same in a housing.

A storage unit according to a first aspect of the present invention includes a storage portion that stores power, a converter that converts power, a first temperature detection portion arranged in the vicinity of the converter, and a housing that houses at least the converter, the first temperature detection portion, and the storage portion. The “vicinity of the converter” denotes an area within half the longest distance between the converter and the inner wall of the housing from the center of the converter.

A power generation system according to a second aspect of the present invention includes a power generation module that generates power with natural energy, interconnected to a power grid and a storage unit including a storage portion that stores power, a converter that converts power, a first temperature detection portion arranged in the vicinity of the converter, and a housing that houses at least the converter, the first temperature detection portion, and the storage portion.

A charge/discharge system according to a third aspect of the present invention includes a storage unit including a storage portion that stores power, a converter that converts power, a first temperature detection portion arranged in the vicinity of the converter, and a housing that houses at least the converter, the first temperature detection portion, and the storage portion and a control portion that controls the converter included in the storage unit, while the control portion stops driving of the converter if determining that a detection temperature detected by the first temperature detection portion has reached at least a prescribed first threshold.

A storage unit according to a fourth aspect of the present invention includes a storage portion that stores power, a converter that converts power, a state detection portion, and a housing that houses at least the converter, the state detection portion, and the storage portion, while the state detection portion detects a state in the housing, and the converter is housed in a box-shaped first housing portion.

Increase in the temperature of the storage portion can be suppressed even when the storage portion is used by housing the same in the housing. Consequently, decrease in the function of the storage portion can be suppressed while the storage portion can be inhibited from being negatively influenced.

### BRIEF DESCRIPTION OF THE DRAWINGS

FIG. 1 is a block diagram showing the structure of a power generation system according to a first embodiment of the present invention;

FIG. 2 is a diagram for illustrating the detailed structures (a first state and a fourth state) of changeover switches of the power generation system according to the first embodiment shown in FIG. 1;

FIG. 3 is a diagram for illustrating the detailed structures (a second state and a third state) of the changeover switches of the power generation system according to the first embodiment shown in FIG. 1;

FIG. 4 is a diagram for illustrating the detailed structures (the second state and the fourth state) of the changeover switches of the power generation system according to the first embodiment shown in FIG. 1;

FIG. 5 is a perspective view showing a storage unit of the power generation system according to the first embodiment of the present invention;

FIG. 6 is a top plan view showing the storage unit of the power generation system according to the first embodiment of the present invention;

FIG. 7 is a sectional view showing the storage unit of the power generation system according to the first embodiment of the present invention; and

FIG. 8 is a block diagram showing the structure of a power generation system according to a second embodiment of the present invention.

### DESCRIPTION OF THE PREFERRED EMBODIMENTS

Embodiments of the present invention are now described with reference to the drawings.

### First Embodiment

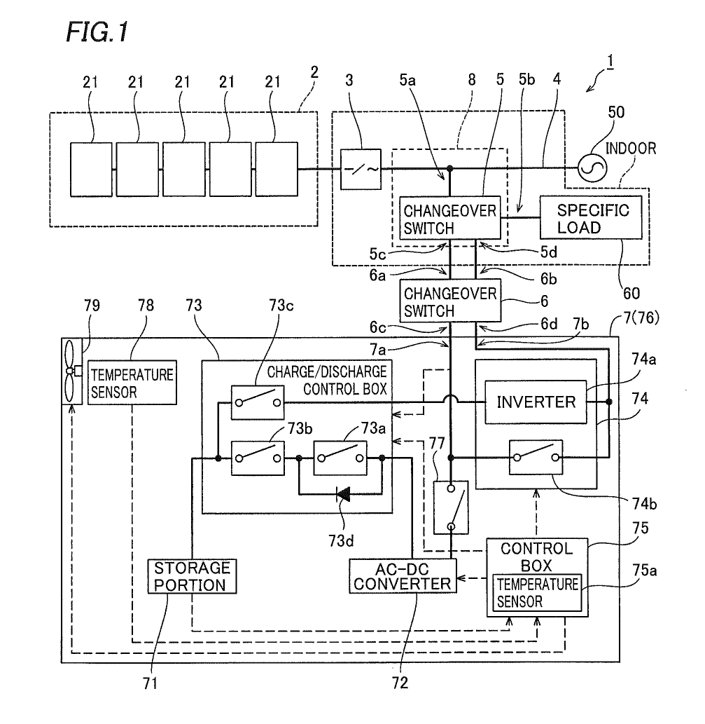

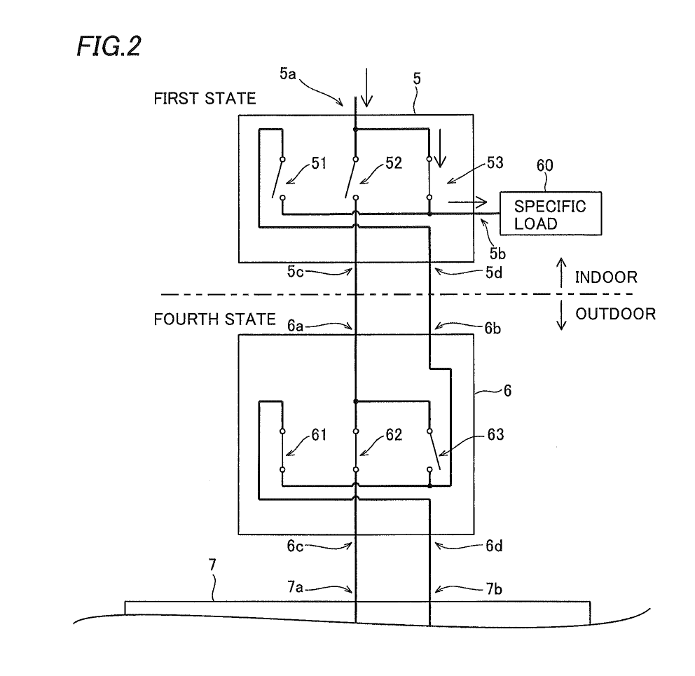

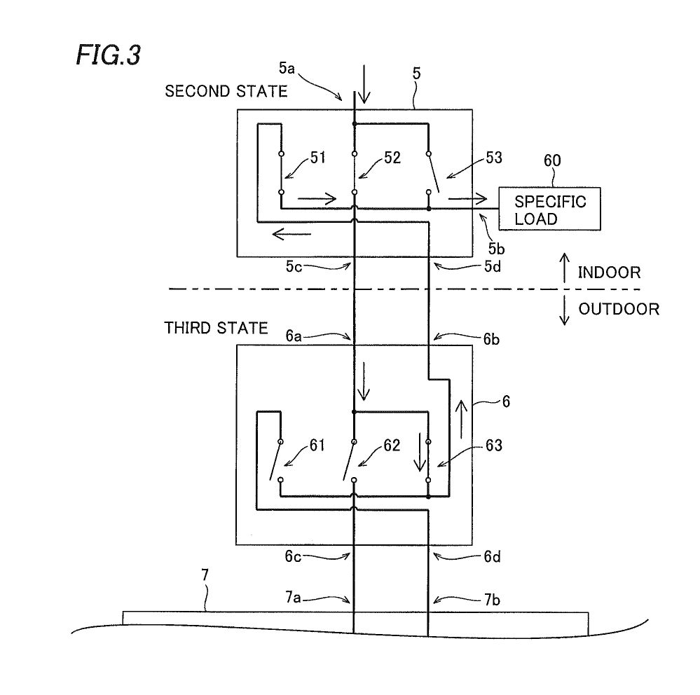

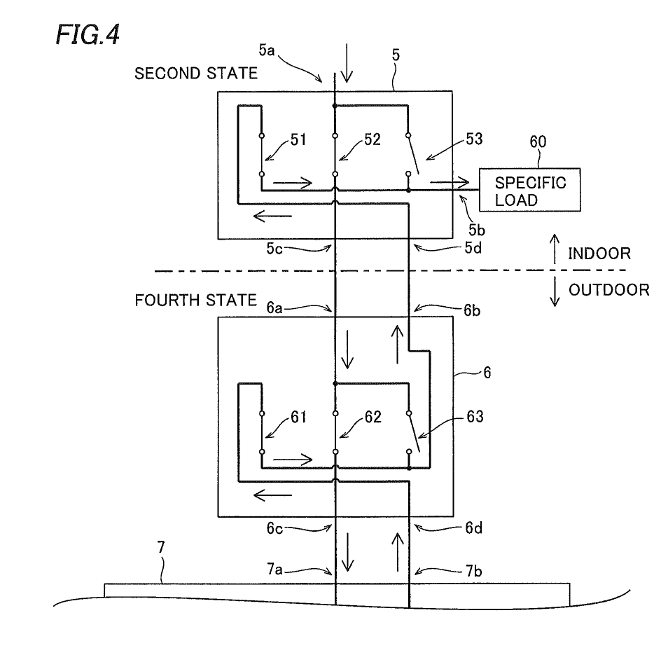

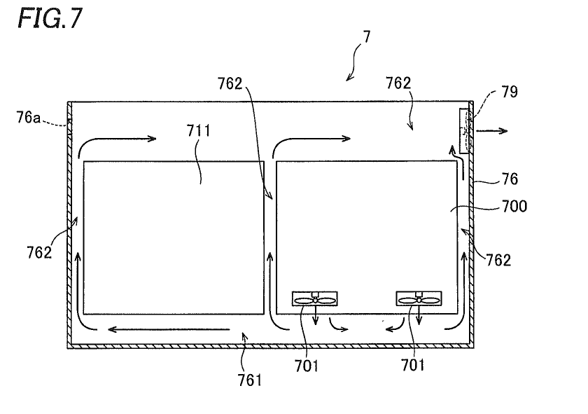

First, the structure of a power generation system (photovoltaic power generation system 1) according to a first embodiment of the present invention is described with reference to FIGS. 1 to 7.

The photovoltaic power generation system 1 includes a generated power output portion 2 outputting power generated with sunlight, an inverter 3 connected to a power grid 50 for outputting the power output from the generated power output portion 2 to the power grid 50 so that a reverse power flow is possible, changeover switches 5 and 6 connected to a bus 4 connecting the inverter 3 and the power grid 50, and a storage unit 7 connected to the changeover switch 6.

The inverter 3 has a function of converting direct-current power output from the generated power output portion 2 to alternating current. The generated power output portion 2 is interconnected to the power grid 50 through the inverter 3.

The changeover switch 5 is connected with a specific load 60. The specific load 60 is an apparatus driven by an alternating-current power source. The specific load 60 includes an apparatus desired to be regularly supplied with power from a power source and required to regularly operate.

The generated power output portion 2 includes a plurality of photovoltaic power generation modules 21 connected in series to each other. The photovoltaic power generation modules 21 can be constituted by various types of solar cells such as thin film silicon-based solar cells, crystalline silicon-based solar cells, or compound semiconductor-based solar cells. The photovoltaic power generation modules 21 are examples of the “power generation module” in the present invention.

The changeover switch 5 is connected to the bus 4 through a wire 5a, and connected to the specific load 60 through a wire 5b. The changeover switch 5 is connected to the changeover switch 6 through wires 5c and 5d and wires 6a and 6b.

This changeover switch 5 includes three changeover switches 51, 52, and 53 inside, and the three changeover switches 51 to 53 are switched on/off simultaneously in response to the user's operation. In other words, a first state where the changeover switches 51, 52, and 53 are turned off, off, and on, respectively, in response to the user's operation and a second state where the changeover switches 51, 52, and 53 are turned on, on, and off, respectively, in response to the user's operation are switched.

In the first state, the wire 5a and the wire 5b are connected to each other through the changeover switch 53 that is turned on, the wire 5a and the wire 5c are disconnected from each other by the changeover switch 52 that is turned off, and the wire 5d and the wire 5b are disconnected from each other by the changeover switch 51 that is turned off. Consequently, in the first state, the bus 4 and the specific load 60 are connected to each other not through the storage unit 7. In this first state, the changeover switch 5 and the changeover switch 6 are electrically disconnected from each other, whereby the bus 4 and the storage unit 7 are electrically separated from each other. Therefore, when the changeover switch 5 is in the first state, power can be supplied from the bus 4 to the specific load 60.

In the second state, the wire 5a and the wire 5b are disconnected from each other by the changeover switch 53 that is turned off, the wire 5a and the wire 5c are connected to each other through the changeover switch 52 that is turned on, and the wire 5d and the wire 5b are connected to each other through the changeover switch 51 that is turned on. In this second state, the changeover switch 5 and the changeover switch 6 are electrically connected to each other. Consequently, the connection target of the bus 4 is switched in response to switching of the changeover switch 6 described later.

The changeover switch 5 is provided in a distribution board 8 placed indoors. The specific load 60 and the inverter 3 are also placed indoors.

The changeover switch 6 is electrically connected with an AC-DC converter 72 through a wire 6c and a wire 7a of the storage unit 7. The changeover switch 6 is connected to an inverter 74a in the storage unit 7 through a wire 6d and a wire 7b of the storage unit 7.

This changeover switch 6 is also switched in response to the user's manual operation similarly to the changeover switch 5. The changeover switch 6 includes three changeover switches 61, 62, and 63 inside, and the three changeover switches 61 to 63 are switched on/off simultaneously in response to the user's operation. In other words, a third state where the changeover switches 61, 62, and 63 are turned off, off, and on, respectively, in response to the user's operation and a fourth state where the changeover switches 61, 62, and 63 are turned on, on, and off, respectively, in response to the user's operation are switched.

In the third state, the wire 6a and the wire 6b are connected to each other through the changeover switch 63 that is turned on, the wire 6a and the wire 6c are disconnected from each other by the changeover switch 62 that is turned off, and the wire 6d and the wire 6b are disconnected from each other by the changeover switch 61 that is turned off. The changeover switch 6 and the storage unit 7 are electrically disconnected from each other, whereby the bus 4 and the storage unit 7 are electrically separated from each other. In the fourth state, the wire 6a and the wire 6b are disconnected from each other by the changeover switch 63 that is turned off, the wire 6a and the wire 6c are connected to each other through the changeover switch 62 that is turned on, and the wire 6d and the wire 6b are connected to each other through the changeover switch 61 that is turned on. The changeover switch 6 and the storage unit 7 are electrically connected to each other, whereby the bus 4 and the storage unit 7 are electrically connected to each other through the changeover switch 5 in the second state.

The changeover switch 5 and the changeover switch 6 can switch a current path independently from each other. In the first embodiment, the changeover switch 5 is switched to the first state indoors, or the changeover switch 6 is switched to the third state outdoors, whereby the bus 4 and the storage unit 7 can be electrically separated from each other. In a state where the storage unit 7 is removed, the changeover switch 5 is switched to the first state, whereby power is directly supplied from either one or both of the power grid 50 and the generated power output portion 2 to the specific load 60 through a current path passing through the wires 5a and 5b. Also when the changeover switch 5 and the changeover switch 6 are switched to the second state and the third state, respectively, in the state where the storage unit 7 is removed, power is directly supplied from either one or both of the power grid 50 and the generated power output portion 2 to the specific load 60 through a current path passing through the wires 5a, 5c, 6a, 6b, 5d, and 5b, similarly.

When the changeover switch 5 is switched to the second state while the changeover switch 6 is switched to the fourth state, the bus 4 and the storage unit 7 are electrically connected to each other through the changeover switch 5 and the changeover switch 6. In this state, the bus 4 and a storage portion 71 of the storage unit 7 are connected to each other while the storage portion 71 and the specific load 60 are connected to each other, as described later. Thus, power from the power grid 50 or the generated power output portion 2 can be stored in the storage portion 71, and the power in the storage portion 71 can be supplied to the specific load 60. Switches inside the storage unit 7 are switched to switch a current path in the storage unit 7, whereby the power from the power grid 50 or the generated power output portion 2 can be supplied to the specific load 60 not the storage portion 71.

Next, the structure of the storage unit 7 is described.

The storage unit 7 mainly includes the storage portion 71 storing the power from the power grid 50, the AC-DC converter 72 converting power from alternating current to direct current, a charge/discharge control box 73 to control charge/discharge of the storage portion 71, an inverter unit 74 to supply power from the storage portion 71 or the bus 4 to the specific load 60, and a control box 75 controlling devices such as the storage portion 71, the AC-DC converter 72, and the charge/discharge control box 73. These devices are collectively housed in a housing 76, and can be treated as a single unit. The storage unit 7 and the control box 75 provided in the storage unit 7 constitute a charge/discharge system of the photovoltaic power generation system 1. In other words, in the first embodiment, the storage unit 7 is so configured as to serve alone as the charge/discharge system of the photovoltaic power generation system 1 by the devices collectively housed in the housing 76. The AC-DC converter 72, the charge/discharge control box 73, the inverter unit 74, and the control box 75 are examples of the “devices of the storage unit” in the present invention, and the AC-DC converter 72 is an example of the “converter” in the present invention. The control box 75 is an example of the “control portion” in the present invention.

In the first embodiment, this storage unit 7 is placed outdoors. The storage unit 7 has the wire 7a to receive power from the power grid 50 and the wire 7b to supply power to the specific load 60. In the power generation system, the wires 7a and 7b are connected to the wires 6c and 6d of the changeover switch 6 provided outdoors, respectively, whereby power from either one or both of the power grid 50 and the generated power output portion 2 can be stored in the storage portion 71, and the stored power can be supplied to the specific load 60.

As the storage portion 71, a secondary battery (lithium ion storage battery, for example) exhibiting a small amount of natural discharge and having high charging/discharging efficiency is employed. The lithium ion storage battery has a property of absorbing heat during charge.

The charge/discharge control box 73 includes three switches 73a, 73b, and 73c capable of being switched on/off by the control box 75. The switches 73a and 73b are connected in series to each other in a charging path between the AC-DC converter 72 and the storage portion 71. A diode 73d rectifying current from the AC-DC converter 72 toward the storage portion 71 is provided on a bypass path provided in parallel with the switch 73a. The switch 73c is provided in a discharging path between the storage portion 71 and the inverter unit 74.

When the storage portion 71 is charged from either one or both of the power grid 50 and the generated power output portion 2, the switch 73b is first turned on, and then the switch 73a is turned on. Thus, the diode 73d can prevent a reverse flow from the storage portion 71 to the AC-DC converter 72, resulting from the low output voltage of the AC-DC converter 72 immediately after start of the AC-DC converter 72.

When power is discharged from the storage portion 71 to the specific load 60 through the inverter unit 74, the switch 73c is turned on. The switch 73a is turned off, and then the switch 73b is turned off. Similarly in this case, the diode 73d can prevent a reverse flow from the storage portion 71 to the AC-DC converter 72. When all the switches 73a, 73b, and 73c are turned on, both the charge and discharge of the storage portion 71 can be performed.

The inverter unit 74 includes the inverter 74a serving as a DC-AC converter to supply power in the storage portion 71 outputting direct-current power to the specific load 60 driven by the alternating-current power source and a switch 74b capable of being switched on/off. The switch 74b is provided between the wire 7a and the wire 7b. The switch 74b is usually turned on, and the inverter 74a turns off the switch 74b when power is supplied to the inverter 74a, and preferably when power of at least a prescribed voltage is supplied to the inverter 74a.

A switch 77 capable of being switched on/off is provided in a portion of a current path between the wire 7a and the AC-DC converter 72 closer to the AC-DC converter 72 beyond a contact point with the switch 74b. This switch 77 is so configured as to be switched on/off in response to the temperature of a temperature sensor 75a provided in the control box 75. In other words, when the temperature of the temperature sensor 75a is not more than a prescribed temperature (about 70° C., for example), the switch 77 is turned on so that power from the bus 4 is supplied to the AC-DC converter 72. When the temperature of the temperature sensor 75a is more than the prescribed temperature, the switch 77 is turned off so that the bus 4 and the AC-DC converter 72 are electrically disconnected from each other. The control box 75 controls ON/OFF of the switch 77. The temperature sensor 75a is an example of the “first temperature detection portion” in the present invention. The temperature of 70° C. is an example of the “first threshold” in the present invention.

The control box 75 is powered from a wire between the switch 77 and the AC-DC converter 72, so that driving of the control box 75 automatically stops because of no power source when the switch 77 is turned off. When the control box 75 stops, output from the AC-DC converter 72 is turned off (power supply to the AC-DC converter 72 is also disrupted), and the switches 73a and 73c are turned off. The switch 73c is turned off, whereby power supply to the inverter 74a is disrupted. The power supply to the inverter 74a is disrupted, whereby the switch 74b is turned on, as described above. The switch 74b is turned on, whereby the power from the bus 4 can be supplied to the specific load 60 not through the storage portion 71 but through a current path passing through the wire 7a, the switch 74b, and the wire 7b when the changeover switch 5 and the changeover switch 6 are in the second state and the fourth state, respectively. The current path passing through the wire 7a, the switch 74b, and the wire 7b is an example of the “second power supply path” in the present invention.

Therefore, when the temperature in the housing 76 is low, the switch 74b and the switch 77 are turned off and on, respectively. When the inside (particularly, the AC-DC converter 72) of the housing 76 is in an abnormally heated state (the temperature in the control box 75 is at least about 70° C., for example), the switch 74b and the switch 77 are turned on and off, respectively. Thus, when the inside of the housing 76 is in the abnormally heated state, the AC-DC converter 72, the storage portion 71, the inverter 74a, and the control box 75 that are heat generating sources can be stopped while the power supply from the bus 4 to the specific load 60 is maintained. Consequently, when the inside (particularly, the AC-DC converter 72) of the housing 76 is in the abnormally heated state, further increase in the temperature can be suppressed so that thermal damage to each device in the housing 76 can be reduced.

In the housing 76, a temperature sensor 78 and an exhaust fan 79 are further provided. When the detection temperature of the temperature sensor 78 is at least a prescribed temperature (about 40° C.), the exhaust fan 79 is driven so that heat in the housing 76 can be exhausted. The temperature sensor 78 and the exhaust fan 79 are not connected to other devices (the storage portion 71, the control box 75, etc.) in the housing 76, but powered from the wire 7a to be driven. Consequently, the temperature sensor 78 and the exhaust fan 79 operate electrically independently from other devices (the storage portion 71, the control box 75, etc.) in the housing 76 even when the switch 77 is turned off. Therefore, the exhaust fan 79 operates independently even when driving of the AC-DC converter 72 stops. The temperature sensor 78 and the exhaust fan 79 are examples of the “second temperature detection portion” and the “exhaust portion” in the present invention, respectively. The temperature of 40° C. is an example of the “second threshold” in the present invention.

The control box 75 has a function of controlling ON/OFF of the output of the AC-DC converter 72, the switches 73a to 73c of the charge/discharge control box 73, the switch 74b of the inverter unit 74, the switch 77, etc. on the basis of the charging amount of the storage portion 71, the detection result of the temperature sensor 75a, the current time (whether or not the current time is in the late night hours), etc. Specifically, if determining that the temperature in the housing 76 (particularly, the AC-DC converter 72) is at least the prescribed temperature (the temperature in the control box 75 is about 70° C., for example) on the basis of the detection result of the temperature sensor 75a, the control box 75 determines that the inside of the housing 76 is in the abnormally heated state, and turns off the switch 77. In a normal state (state that is not the abnormally heated state), the control box 75 controls ON/OFF of the switches of the charge/discharge control box 73, the output of the AC-DC converter 72, the switch 74b of the inverter unit 74, etc. on the basis of a prescribed program or the like.

The control box 75 controls each switch to charge the storage portion 71 from the power grid 50 late at night, for example, in the normal operation and supply power from the storage portion 71 to the specific load 60 at any time of the day or night when power supply to the specific load 60 is required. A current path to charge the storage portion 71 by supplying power from the bus 4 to the storage portion 71 is a path passing through the wire 7a, the switch 77, the AC-DC converter 72, the switch 73a, and the switch 73b. A current path to supply power to the specific load 60 by discharging the storage portion 71 is a path passing through the switch 73c, the inverter 74a, and the wire 7b. The power stored in the storage portion 71 is not supplied to the power grid 50. The path passing through the switch 73c, the inverter 74a, and the wire 7b is an example of the “first power supply path” in the present invention. In the first embodiment, the control box 75 controls the discharge of the storage portion 71 so that the residual capacity of the storage portion 71 does not fall to a prescribed threshold (50% of a fully-charged state, for example) or less even when the storage portion 71 is discharged in the normal operation. If determining that the amount of power stored in the storage portion 71 has fallen to the threshold or less, the control box 75 stops power supply from the storage portion 71 to the specific load 60, and switches each switch to supply power directly from the bus 4 to the specific load 60. Specifically, the control box 75 turns off the switch 73c of the charge/discharge control box 73 and turns on the switch 74b of the inverter unit 74. In this case, the output of the AC-DC converter 72 is turned off, and no power charge is performed in the daytime hours. If the voltage of power reversely flowing from a consumer exceeds the allowable voltage of a distribution line, or the amount of power demand is expected to fall much below the amount of power generation, the control box 75 controls the AC-DC converter 72 and each switch to charge the storage portion 71.

In a time of emergency such as a power outage, power supply from the power grid 50 is stopped, so that the control box 75 is stopped. Furthermore, the switch 77 and the switches 73a and 73b are turned off. Thus, power is not supplied to the AC-DC converter 72, so that the driving of the AC-DC converter 72 is also stopped. A voltage line signal of the wire 7a is input to the switch 73c, and detects that no voltage is applied to the wire 7a in the case of a power outage, whereby the switch 73c is turned on. The inverter 74a is so configured as to be activated by power supply from the storage portion 71.

The control box 75 controls the discharge of the storage portion 71 so that the residual capacity of the storage portion 71 does not fall to the prescribed threshold (50%, for example) or less in the normal operation. Consequently, a larger amount of power than the threshold (50% of the fully charged state) is certainly stored in the storage portion 71 when the discharge of the storage portion 71 to the specific load 60 starts in the time of emergency such as a power outage. In the case of a power outage, the control box 75 controls the charge/discharge control box 73 to discharge the storage portion 71 even if the amount of power stored in the storage portion 71 falls to the prescribed threshold (50% of the fully-charged state) or less, dissimilarly in the normal operation. In the time of emergency, power supply to the control box 75 is stopped, and the switch 73c cannot be switched on/off. However, the stored power can be effectively utilized by employing a lithium ion storage battery, for example, as in the first embodiment.

Next, the detailed structure of the storage unit 7 is described.

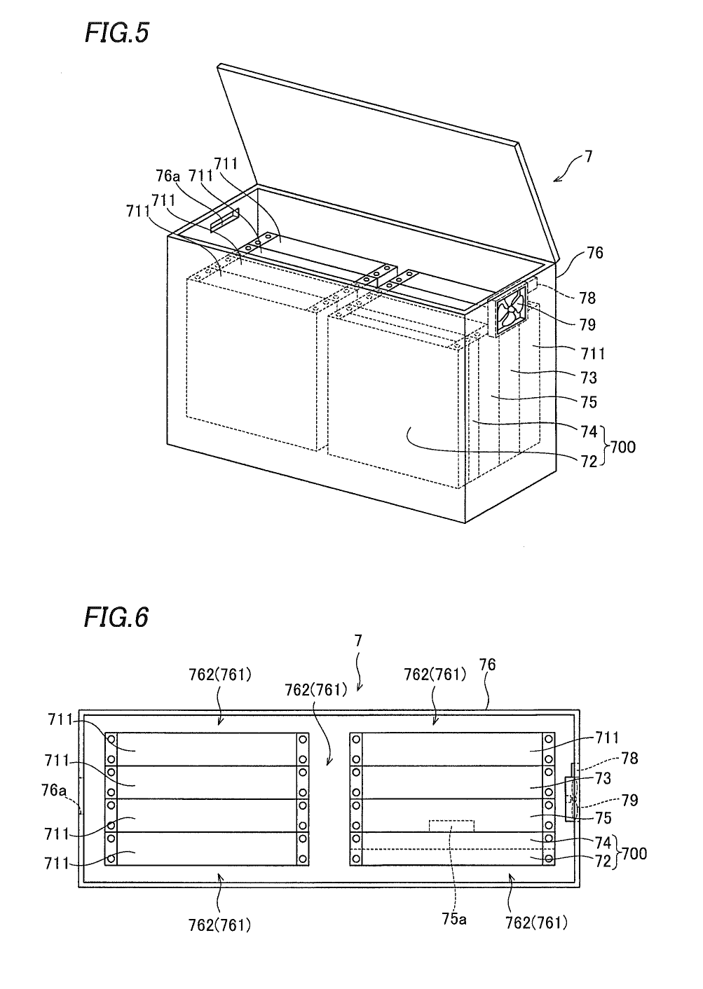

As shown in FIGS. 5 to 7, in the first embodiment, the storage unit 7 includes five lithium ion storage batteries 711 each in the form of a box, the charge/discharge control box 73 in the form of a box, the control box 75 in the form of a box, and a power conversion unit 700 in the form of a box constituted by the inverter unit 74 and the AC-DC converter 72 that are integrally formed, all housed in the housing 76 in the form of a box. The lithium ion storage batteries 711 each are a storage battery unit in the form of a pack having a plurality of lithium ion storage battery cells inside. The five lithium ion storage batteries 711 constitute the storage portion 71. These eight devices (the five lithium ion storage batteries 711, the charge/discharge control box 73, the control box 75, and the power conversion unit 700) are adjacently arranged in a transverse direction. The control box 75 and the power conversion unit 700 are adjacent to each other. In other words, the temperature sensor 75a of the control box 75 is arranged in the vicinity of the power conversion unit 700 (particularly, the AC-DC converter 72). In the power conversion unit 700, the inverter unit 74 is arranged on the side closer to the control box 75. In other words, the AC-DC converter 72 is arranged in a position separated from the control box 75 through the inverter unit 74. The power conversion unit 700 and the control box 75 are examples of the “first housing portion” and the “second housing portion” in the present invention, respectively.

The temperature sensor 75a of the control box 75 is arranged on the side closer to the inverter unit 74. The exhaust fan 79 is provided on an upper side surface of the housing 76, and the temperature sensor 78 is arranged on the upper portion of the housing 76 adjacent to the exhaust fan 79. An air intake 76a is formed in the upper portion of the housing 76. The air intake 76a is formed in a side surface opposed to the side surface of the housing 76 on which the exhaust fan 79 and the temperature sensor 78 are arranged. In other words, the temperature sensor 78 is arranged in a position separated from the air intake 76a, and arranged in a position closer to the exhaust fan 79 than the air intake 76a. During driving of the exhaust fan 79, outside air is taken from the air intake 76a, and exhausted by the exhaust fan 79. Heat is accumulated in the upper portion of the housing 76, and hence the heat can be efficiently exhausted from the air intake 76a and the exhaust fan 79 both arranged in the upper portion of the housing 76.

Two heat radiation fans 701 are integrally provided in the lower portion of the power conversion unit 700 to exhaust heat generated by driving of the AC-DC converter 72 and the inverter 74a from the power conversion unit 700. These heat radiation fans 701 are arranged to allow air to blow downward from the lower surface of the power conversion unit 700. The heat radiation fans 701 are examples of the “air blowing portion” in the present invention.

An air circulation path 761 is provided between the inner bottom surface of the housing 76 and each device (the lithium ion storage batteries 711, the charge/discharge control box 73, the control box 75, the power conversion unit 700, etc.). An air circulation path 762 vertically extending to the exhaust fan 79, brought into communication with the air circulation path 761 is provided between the inner side surfaces of the housing 76 and each device and between each device (in the central portion in the housing 76). Thus, air containing heat, sent by the heat radiation fans 701 is circulated in the housing 76 through the air circulation path 761 in the lower portion of the housing 76. Thereafter, the air sent by the heat radiation fans 701 rises along the side surfaces of each device through the air circulation path 762, and is sent to the exhaust fan 79 in the upper portion of the housing 76. Consequently, local heat in the housing 76 is efficiently diffused by the heat radiation fans 701, and efficiently exhausted by the exhaust fan 79 through the air circulation path 762. The air circulation path 762 is an example of the “venting path” in the present invention.

In the storage unit 7, heat exhausted from the power conversion unit 700 into the housing 76 is utilized to heat the lithium ion storage batteries 711. In order to suppress excessive increase in the temperature in the housing 76 resulting from the heat exhausted from the power conversion unit 700 and direct sunlight, the heat accumulated in the housing 76 is exhausted from the upper portion of the housing 76 through the exhaust fan 79 when the temperature in the housing 76 (temperature detected by the temperature sensor 78) is higher than the prescribed temperature (about 40° C.). Each of the lithium ion storage batteries 711, the charge/discharge control box 73, and the power conversion unit 700 are provided with communication portions (not shown) to communicate states (temperature states, for example) of these devices to the control box 75. The communication portions of the lithium ion storage batteries 711 are daisy-chained in series to each other, and are so configured that the five lithium ion storage batteries 711 are treated as a unit.

The temperature sensor 75a is provided to detect the temperature in the housing 76, whereby temperature increase can be detected by the temperature sensor 75a if the temperature (particularly, the temperature of the AC-DC converter 72 generating a large amount of heat) in the housing 76 increases. Thus, the operation for suppressing excessive increase in the temperature in the housing 76 can be started promptly on the basis of the temperature detection of the temperature sensor 75a. Thus, increase in the temperature of the storage portion 71 can be suppressed even when the storage portion 71 is used by housing the same in the housing 76. Consequently, decrease in the function of the storage portion 71 can be suppressed while the storage portion 71 can be inhibited from being negatively influenced.

If determining that the temperature in the housing 76 has reached at least 70° C. on the basis of the detection result of the temperature sensor 75a, the control box 75 stops the driving of the AC-DC converter 72. Thus, the driving of the AC-DC converter 72 generating a largest amount of heat of the devices housed in the housing 76 can be stopped if the temperature in the housing 76 has reached at least 70° C., and hence excessive increase in the temperature in the housing 76 can be effectively suppressed.

If determining that the temperature in the housing 76 has reached at least 70° C. on the basis of the detection result of the temperature sensor 75a, the control box 75 stops the driving of the AC-DC converter 72 and the inverter 74a. According to this structure, the driving of not only the AC-DC converter 72 but also the inverter 74a can be stopped if the temperature in the housing 76 has reached at least 70° C., and hence excessive increase in the temperature in the housing 76 can be further effectively suppressed.

If determining that the temperature in the housing 76 has reached at least 70° C. on the basis of the detection result of the temperature sensor 75a, the control box 75 stops the driving of the AC-DC converter 72, and stops driving of devices for charging the storage portion 71 through the AC-DC converter 72 and discharging the storage portion 71 through the path passing through the switch 73c, the inverter 74a, and the wire 7b. According to this structure, the driving of devices for charging the storage portion 71 through the AC-DC converter 72 and discharging the storage portion 71 through the path passing through the switch 73c, the inverter 74a, and the wire 7b is stopped while the driving of the AC-DC converter 72 is stopped, and hence driving of the storage portion 71 itself can be stopped. Consequently, charge and discharge at a high temperature are inhibited, and degradation of the storage portion 71 can be suppressed.

If determining that the temperature in the housing 76 has reached at least 70° C. on the basis of the detection result of the temperature sensor 75a, the control box 75 stops driving of at least one of the devices of the storage unit 7, other than the device on the current path passing through the wire 7a, the switch 74b, and the wire 7b. According to this structure, power supply from the storage portion 71 to the prescribed load through the current path passing through the wire 7a, the switch 74b, and the wire 7b can be continued while heat generation is inhibited by stopping the driving of the device such as the AC-DC converter 72 that is a heat generating source.

If determining that the temperature in the housing 76 has reached at least the prescribed temperature of 40° C. lower than 70° C. on the basis of the detection result of the temperature sensor 78, the control box 75 drives the exhaust fan 79. According to this structure, exhaust by the exhaust fan 79 is started when the temperature in the housing 76 reaches at least the prescribed temperature of 40° C. lower than 70° C., and hence increase in the temperature in the housing 76 to 70° C. can be suppressed.

The temperature sensor 78 housed in the housing 76 and arranged in the upper portion of the housing 76 is provided, whereby the heat in the housing 76 moves upward, and hence increase in the temperature in the housing 76 can be detected promptly by the temperature sensor 78 arranged in the upper portion of the housing 76.

The exhaust fan 79 exhausting air out of the housing 76 on the basis of the detection result of the temperature sensor 78 is provided, whereby the heat in the housing 76 can be automatically exhausted by the exhaust fan 79 if the temperature in the housing 76 increases, and hence increase in the temperature in the housing 76 can be effectively suppressed.

A distance between the temperature sensor 78 and the exhaust fan 79 is rendered shorter than a distance between the temperature sensor 78 and the air intake 76a, whereby the temperature sensor 78 can be distanced from the vicinity of the air intake 76a where the temperature is further lowered by outside air as compared with other areas in the housing 76, and the temperature is first lowered when exhaust by the exhaust fan 79 is performed. Thus, the temperature sensor 78 can accurately detect the temperature in the housing 76, and hence exhaust by the exhaust fan 79 can be inhibited from being stopped when the temperature in the housing 76 really has not sufficiently decreased.

Next, a specific example of the aforementioned photovoltaic power generation system 1 according to the first embodiment is described.

In this example, the capacity of the storage portion 71 is set at 7.85 kWh while the output power of the AC-DC converter 72 is set at 1.5 kW, and the photovoltaic power generation system 1 is so designed as to spend at least a half of midnight power hours (8 hours from 23:00 to 7:00, for example) charging the storage portion 71 from a zero state to the fully-charged state. In this case, a simple calculation shows that charging time is at least 5 hours. In a lithium ion storage battery, the charging rate must be slowed as full charge approaches, and hence actual charging time is further increased.

If the power consumption of the specific load 60 is set at about 600 Wh, an amount of power of about 3 kWh is required to drive the specific load 60 for 5 hours. If power is supplied from the storage portion 71 to the specific load 60 in the case of a five-hour power outage, the storage portion 71 must have a capacity of at least about 3 kWh. The discharge of the storage portion 71 is controlled to stop when the residual capacity of the storage portion 71 falls to 50% of the capacity of the storage portion 71, so that a capacity of at least about 6 kWh is required to continuously drive the specific load 60 with a capacity of 50% of the fully-charged state in the case of a five-hour power outage. To be safe, a value of 7.85 kWh larger than 6 kWh is determined.

The photovoltaic power generation system 1 is designed on the assumption that the power stored in the storage portion 71 is not fully discharged in a short time but output over a long time. Fully discharging the stored power in a short time in the daytime hours is unlikely to lead to reduction in the daytime power generation capacity. Preferably, the amount of power used by the specific load 60 per day is smaller than the storage capacity, and is so set that the specific load 60 can be driven for at least five hours with the power stored in the storage portion 71. If the specific load 60 is not employed, it is difficult to set the amount of load, and it is also difficult to properly set the capacity of the storage portion 71. In this example, the power rating of the inverter 74a is set at 1 kW, and the power consumption of the specific load 60 is set at about 1 kW at a maximum.

On the assumption of the aforementioned structure of the example, a difference between a case of employing a lithium ion storage battery as the storage portion 71 and a case of employing a lead storage battery as the storage portion 71 is now described.

The volume energy density of the lead storage battery is about 50 Wh/L to 100 Wh/L, and the volume energy density of the lithium ion storage battery is about 400 Wh/L to 600 Wh/L. Therefore, if the volume energy densities of the lead storage battery and the lithium ion storage battery are set at 100 Wh/L and 500 Wh/L, respectively, a difference between the volume energy densities is five times. In other words, if the storage portion is housed in the housing 76, the volume of the housing 76 in a case of the lead storage battery must be about five times the volume of the housing 76 in a case of the lithium ion storage battery. In this case, a difference between the surface areas of the housing 76 is about twice. The surface area of the housing 76 is conceivably proportionate to the radiation amount of the housing 76, and hence a difference in the amount of heat required to increase the temperature in the housing 76 to a given temperature between the lead storage battery and the lithium ion storage battery is about ten times on the basis of the volume ratio (about five times) of the housing 76 and the surface area ratio (about twice) of the housing 76.

The amount of heat generation of the AC-DC converter 72 that is a heat generating source in the first embodiment is proportionate to the output value of the AC-DC converter 72, and the output value of the AC-DC converter 72 is determined depending on the capacity of the storage portion 71, as assumed above, whereby if the capacities of the lead storage battery and the lithium ion storage battery are the same, the amount of heat generation of the AC-DC converter 72 in the case of the lead storage battery and the amount of heat generation of the AC-DC converter 72 in the case of the lithium ion storage battery are also the same. Therefore, the effect of increasing the temperature in the housing 76 due to heat generation of the AC-DC converter 72 in the case of the lead storage battery is about one-tenth of that in the case of the lithium ion storage battery.

In view of the above, in a case of employing the lithium ion storage battery as the storage portion 71, the temperature in the housing 76 is easily increased by heat exhausted from a device such as the AC-DC converter 72, as compared with a case of employing the lead storage battery, and hence temperature detection by the temperature sensors 75a and 78 is more important.

### Second Embodiment

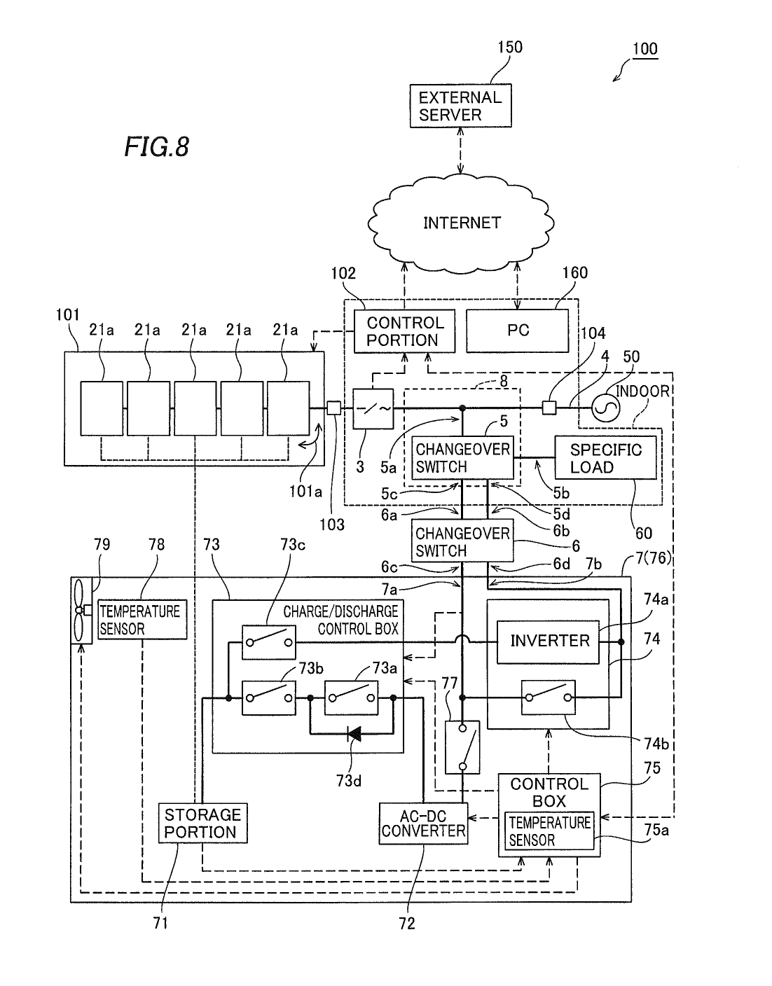

A power generation system (photovoltaic power generation system 100) according to a second embodiment of the present invention is now described with reference to FIG. 8. In this second embodiment, power generated by a plurality of photovoltaic power generation modules 21a is directly supplied to a storage portion 71, dissimilarly to the aforementioned first embodiment.

A generated power output portion 101 includes the plurality of photovoltaic power generation modules 21a connected to each other and a switching circuit portion 101a selectively switchably connecting the power generated by the photovoltaic power generation modules 21a to the side of an inverter 3 or to the side of the storage portion 71.

The switching circuit portion 101a is so configured as to electrically disconnect the generated power output portion 101 and the storage portion 71 from each other in a case of connecting the generated power output portion 101 to the side of the inverter 3, and as to electrically disconnect the generated power output portion 101 and the inverter 3 from each other in a case of connecting the generated power output portion 101 to the side of the storage portion 71. Furthermore, the switching circuit portion 101a is capable of switching a connection state between the five photovoltaic power generation modules 21a to a series connection state where the five photovoltaic power generation modules 21a are connected in series to each other in the case of connecting the generated power output portion 101 to the side of the inverter 3. In addition, the switching circuit portion 101a is capable of switching the connection state between the five photovoltaic power generation modules 21a to a parallel connection state where the five photovoltaic power generation modules 21a are connected in parallel to each other in the case of connecting the generated power output portion 101 to the side of the storage portion 71.

A control portion 102 has a function of transmitting a control command to a control box 75 of a storage unit 7 and receiving information related to the storage unit 7 such as the amount of power stored in the storage portion 71 from the control box 75 on the basis of the amount of power generation of the generated power output portion 101, the charging amount of the storage portion 71, the operating situation of the inverter 3, preset set information, etc. The control portion 102 also has a function of controlling the switching circuit portion 101a of the generated power output portion 101 etc. on the basis of the amount of power generation of the generated power output portion 101, the charging amount of the storage portion 71, the operating situation of the inverter 3, the preset set information, etc. More specifically, the control portion 102 determines whether the system is in normal operation or in an emergency state on the basis of the charging amount of the storage portion 71, the operating situation of the inverter 3, the preset set information, etc. The storage unit 7 and the control box 75 constitute a charge/discharge system of the photovoltaic power generation system 100, and the storage unit 7 and the control portion 102 also constitute the charge/discharge system of the photovoltaic power generation system 100.

If determining that the system is in the normal operation, the control portion 102 controls the switching circuit portion 101a to bring the photovoltaic power generation modules 21a into the series connection state and switch the connection target of the generated power output portion 101 to the side of the inverter 3. In the normal operation, power output from the generated power output portion 101 is consumed in a specific load 60 or the like, and surplus power is made to reversely flow into a power grid 50.

If determining that the system is in the emergency state, the control portion 102 controls the switching circuit portion 101a to bring the photovoltaic power generation modules 21a into the parallel connection state and switch the connection target of the generated power output portion 101 to the side of the storage portion 71. In the emergency state, the power output from the generated power output portion 101 is supplied to the storage portion 71, and the specific load 60 is driven by the charging power of the storage portion 71 and the power output from the generated power output portion 101.

The control portion 102 can detect the amount of power generation of the photovoltaic power generation modules 21a, the amount of reverse flow power, the amount of power consumed by the specific load 60, etc. on the basis of the detection results of a current detection portion 103 provided on the side of the inverter 3 closer to the generated power output portion 101 and a current detection portion 104 provided on the side of the inverter 3 closer to the power grid 50. Furthermore, the control portion 102 is so configured as to transmit the amount of power generation of the photovoltaic power generation modules 21a, the amount of reverse flow power, the amount of power consumed by the specific load 60, the state (the charging amount, the temperature state, etc.) of the storage portion 71, and another kind of information related to the photovoltaic power generation system 100 to an external server 150 through the Internet. This external server 150 is a server of a maintenance company of the photovoltaic power generation system 100, for example. Thus, the maintenance company can grasp the state of the photovoltaic power generation system 100 any time. This external server 150 can be accessed from a PC (personal computer) 160 or the like of a user through the Internet, and the user can confirm the state of his/her own photovoltaic power generation system 100 with the PC 160.

The remaining structure of the photovoltaic power generation system 100 according to the second embodiment is similar to that of the photovoltaic power generation system 1 according to the aforementioned first embodiment.

According to the second embodiment, in a time of emergency, the power generated by the photovoltaic power generation modules 21a can be stored in the storage portion 71, and hence the specific load 60 can be driven for a longer time.

The remaining effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the photovoltaic power generation modules generate power in each of the aforementioned first and second embodiments, the present invention is not restricted to this, but power generation modules such as other direct current generators or wind turbine generators generating power with another natural energy may be employed as power generation modules.

While the lithium ion storage batteries 711 are employed as the storage portion 71 in each of the aforementioned first and second embodiments, the present invention is not restricted to this, but other secondary batteries may be employed. For example, storage batteries such as nickel-hydrogen storage batteries or lead storage batteries may be employed. Furthermore, capacitors may be employed in place of the storage batteries as an example of the “storage portion” in the present invention.

While the apparatus driven by an alternating-current power source is shown as an example of the specific load 60 in each of the aforementioned first and second embodiments, an apparatus driven by a direct-current power source may be employed. In this case, a DC-DC converter performing DC-DC voltage conversion is employed between the storage portion 71 and the specific load 60 in place of the inverter 74a converting direct current to alternating current. Alternatively, the storage portion 71 and the specific load 60 are directly connected to each other. Furthermore, a direct-current load and an alternating-current load may be mixed as the specific load 60.

While the temperature sensor 78 and the exhaust fan 79 are provided in the storage unit 7 in each of the aforementioned first and second embodiments, the present invention is not restricted to this, but neither the temperature sensor 78 nor the exhaust fan 79 may be provided.

While among the devices, the power conversion unit 700 is arranged in an end of the interior of the housing 76 in each of the aforementioned first and second embodiments, the present invention is not restricted to this, but the arrangement of the power conversion unit 700 may be properly changed. For example, the AC-DC converter 72 and the inverter unit 74 may be separated from each other, and the control box 75 having the temperature sensor 75a may be arranged between the AC-DC converter 72 and the inverter unit 74.

While the lithium ion storage batteries 711, the charge/discharge control box 73, the power conversion unit 700, and the control box 75 are arranged side by side in each of the aforementioned first and second embodiments, the present invention is not restricted to this, but all or some of these devices may be arranged vertically.

While the changeover switches 5 and 6 are provided in each of the aforementioned first and second embodiments, the present invention is not restricted to this, but only either the changeover switch 5 or 6 may be provided, or no changeover switch may be provided.

While the storage unit 7 is placed outdoors in each of the aforementioned first and second embodiments, the present invention is not restricted to this, but the storage unit 7 may be placed indoors.

While the temperature sensor 75a serving as the “first temperature detection portion” is provided in the control box 75 in each of the aforementioned first and second embodiments, the present invention is not restricted to this, but the temperature sensor 75a may be provided outside the control box 75.

While the “first threshold” and the “second threshold” are 70° C. and 40° C., respectively in each of the aforementioned first and second embodiments, the present invention is not restricted to this, but temperatures other than 70° C. and 40° C. may be employed.

While in the structure provided with no device on the current path (second power supply path) passing through the wire 7a, the switch 74b, and the wire 7b, the device such as the AC-DC converter 72 is stopped when the temperature reaches at least 70° C. in each of the aforementioned first and second embodiments, the present invention is not restricted to this. In other words, in a structure provided with a device on the second power supply path, a device other than the device on the second power supply path may be stopped when the temperature reaches at least 70° C. Thus, power can be continuously supplied to the load through the second power supply path even if the device such as the AC-DC converter 72 is stopped.

What is claimed is:

1. A storage unit comprising:
a storage portion that stores power;
a converter that converts power;
a first temperature detection portion arranged in a vicinity of said converter; and
a housing that houses at least said converter, said first temperature detection portion, and said storage portion.

2. The storage unit according to claim 1, further comprising a control portion that controls said converter, housed in said housing, wherein
said control portion stops driving of said converter if determining that a detection temperature detected by said first temperature detection portion has reached at least a prescribed first threshold.

3. The storage unit according to claim 2, further comprising an inverter housed in said housing, wherein
said control portion stops driving of said converter and said inverter if determining that said detection temperature detected by said first temperature detection portion has reached at least said first threshold.

4. The storage unit according to claim 2, further comprising a first power supply path to supply power from said storage portion to a prescribed load, wherein
said control portion stops said driving of said converter and driving of a device to charge said storage portion through said converter and discharge said storage portion through said first power supply path if determining that said detection temperature detected by said first temperature detection portion has reached at least said first threshold.

5. The storage unit according to claim 2, further comprising a second power supply path to supply power from a power grid to a prescribed load not through said storage portion, wherein
said control portion stops driving of at least one of devices of said storage unit, other than a device on said second power supply path if determining that said detection temperature detected by said first temperature detection portion has reached at least said first threshold.

6. The storage unit according to claim 2, further comprising:
a second temperature detection portion housed in said housing to detect a temperature in said housing; and
an exhaust portion to exhaust air out of said housing, wherein
said control portion drives said exhaust portion if determining that a detection temperature detected by said second temperature detection portion has reached at least a prescribed second threshold lower than said first threshold.

7. The storage unit according to claim 6, wherein
said exhaust portion is configured to operate independently even if said driving of said converter is stopped.

8. The storage unit according to claim 1, further comprising a second temperature detection portion housed in said housing and arranged in an upper portion of said housing to detect a temperature in said housing.

9. The storage unit according to claim 8, further comprising an exhaust portion that exhausts air out of said housing based on a detection result of said second temperature detection portion.

10. The storage unit according to claim 9, further comprising an air intake on said housing to take in outside air, wherein
a distance between said second temperature detection portion and said exhaust portion is shorter than a distance between said second temperature detection portion and said air intake.

11. The storage unit according to claim 10, wherein
said air intake is provided in a second side surface of said housing opposed to a first side surface of said housing provided with said exhaust portion.

12. The storage unit according to claim 9, wherein
said exhaust portion is arranged in an inner upper portion of said housing.

13. The storage unit according to claim 9, wherein
a venting path that passes along a side surface of at least any one of devices housed in said housing, connected to said exhaust portion is provided in said housing.

14. The storage unit according to claim 1, wherein
said converter is housed in a box-shaped first housing portion,
said first temperature detection portion is housed in a box-shaped second housing portion, and
said first housing portion and said second housing portion are arranged adjacent to each other in said housing.

15. A power generation system comprising:
a power generation module that generates power with natural energy, interconnected to a power grid; and
a storage unit including a storage portion that stores power, a converter that converts power, a first temperature detection portion arranged in a vicinity of said converter, and a housing that houses at least said converter, said first temperature detection portion, and said storage portion.

16. A charge/discharge system comprising:
a storage unit including a storage portion that stores power, a converter that converts power, a first temperature detection portion arranged in a vicinity of said converter, and a housing that houses at least said converter, said first temperature detection portion, and said storage portion; and
a control portion that controls said converter included in said storage unit, wherein
said control portion stops driving of said converter if determining that a detection temperature detected by said first temperature detection portion has reached at least a prescribed first threshold.

17. A storage unit comprising:
a storage portion that stores power;
a converter that converts power;
a state detection portion; and
a housing that houses at least said converter, said state detection portion, and said storage portion, wherein
said state detection portion detects a state in said housing, and
said converter is housed in a box-shaped first housing portion.
